(19) United States
(12) Patent Application Publication
(10) Pub. No.: US 2008/0316077 A1
(43) Pub. Date: Dec. 25, 2008

(54) D/A CONVERTER

(75) Inventor: Yuichi Matsuo, Mizuho-Shi (JP)

Correspondence Address: CANTOR COLBURN, LLP, 20 Church Street, 22nd Floor, Hartford, CT, 06103, US

(73) Assignees: SANYO ELECTRIC CO., LTD., Osaka (JP); SANYO Semiconductor Co., Ltd., Gunma (JP)

(21) Appl. No.: 11/863,784

(22) Filed: Sep. 28, 2007

(30) Foreign Application Priority Data
Sep. 28, 2006 (JP) JP2006-263959

(51) Int. Cl. H03M 1/66

(52) U.S. Cl. 341/144

(57) ABSTRACT

An output from a resister string is selected with a signal of m upper bits of an input digital signal and converted to a pair of analog signals (VH, VL) having a width corresponding to n lower bits. The signals (VH, VL) are divided using a resistor string and converted to an along signal selected according to the signal of n lower bits, so that an input digital signal of (n+m) bits (where each of n and m is an integer greater than or equal to 2) is converted into an analog signal.

### CROSS-REFERENCE TO RELATED APPLICATIONS

The entire disclosure of Japanese Patent Application No. 2006-263959 including specification, claims, drawings, and abstract is incorporated herein by reference.

### BACKGROUND OF THE INVENTION

1. Field of the Invention

The present invention relates to a D/A converter which converts an input digital signal to an analog signal.

2. Description of the Related Art

D/A converters (digital-to-analog converters) which convert a digital signal into an analog signal are known in the related art. In many cases, various signal processes are digitally executed and, the D/A converter is widely in use in a driver circuit which drives a load or the like. For example, a D/A converter which converts a digital video signal into an analog signal for driving liquid crystal in each pixel is used in a driver circuit of a liquid crystal display apparatus (hereinafter referred to as “LCD”).

A resolution of a display on an LCD is increasing, and a number of bits of the video signal is consequently increasing. More specifically, the number of bits which has been approximately 6 bits is increased to 8 bits, and, recently, a video signal of 10 bits is employed. In addition, because the number of pixels is also increasing, pixels of one row must be divided into a plurality of channels and driven in parallel to each other, and, in many recent structures, the number of channels of 10 or more is not rare.

A circuit size of the D/A converter of such a driver circuit having a high resolution would inevitably be increased. For example, when a digital signal of 10 bits is to be converted into an analog signal using a resistor string, 2¹⁰, or 1024 resistors are required, and, a gradation line for extracting an analog signal of each gradation and selectors corresponding to the gradation lines must be provided.

On the other hand, there is a demand for minimizing a peripheral region for the display section, and to shorten a length along the column direction. In particular, when the driver circuit is to be formed as a separate IC (Integrated Circuit) chip and mounted on a substrate of the LCD through COG (Chip On Glass) technology, there is a demand for forming the chip in an elongated shape.

### SUMMARY OF THE INVENTION

According to one aspect of the present invention, there is provided a digital-to-analog converter which converts an input digital signal of (n+m) bits (where each of n and m is an integer greater than of equal to 2) into an analog signal, the digital-to-analog converter comprising an upper conversion section which comprises a resistor string and which converts a signal of m upper bits of the input digital signal into a pair of analog signals corresponding to the signal of the m upper bits and having a width corresponding to n lower bits, and a lower conversion section which comprises a resistor string, which divides a pair of outputs from the upper conversion section, and which converts into an analog signal selected according to a signal of n lower bits.

According to another aspect of the present invention, it is preferable that the digital-to-analog converter further comprises a pair of buffer amplifiers which stabilize the pair of outputs from the upper conversion section, respectively.

According to another aspect of the present invention, it is preferable that, in the digital-to-analog converter, the upper conversion section outputs a pair of analog signals having a width of p bits (where p is an integer greater than n), and the lower conversion section selects an output based on a signal of n bits using a portion within a conversion width of p bits corresponding to n bits.

According to another aspect of the present invention, it is preferable that, in the digital-to-analog converter, when the input digital signal has a large value or a small value which is outside of an operation guarantee range, the lower conversion section outputs an output using a portion other than the portion corresponding to n bits.

According to yet another aspect of the present invention, it is preferable that, in the digital-to-analog converter, a plurality of the lower conversion sections having an identical structure are provided, and one of the outputs is selected according to a correction bit which is supplied separately from the input digital signal.

According to various aspects of the present invention, because the resistor string is divided into a portion corresponding to upper bits of an input signal and a portion corresponding to lower bits, the total number of resisters can be reduced. Because of this, the chip can be more easily formed in an elongated shape when circuits are integrated.

In addition, by setting an output width of the upper conversion unit to a larger value and using a resistor string corresponding to a number of bits which is larger than necessary in the lower conversion unit, it is possible to reduce generation of an error due to division of the resistor string.

### BRIEF DESCRIPTION OF THE DRAWINGS

A preferred embodiment of the present invention will be described in detail by reference to the drawings, wherein:

FIG. 1 is a diagram showing a structure of a preferred embodiment of the present invention;

FIG. 2 is a diagram showing a detailed structure of a preferred embodiment of the present invention;

FIG. 3 is a diagram showing a structure of another preferred embodiment of the present invention;

FIG. 4 is a diagram showing a structure of a correction by correction data;

FIG. 5 is a diagram showing a structure of a correction using a fuse circuit;

FIG. 6 is a diagram explaining reading of a fuse circuit;

FIG. 7 is a diagram showing a structure of application to a liquid crystal display apparatus; and

FIG. 8 is a diagram showing a structure of a drive control circuit of a display apparatus.

### DESCRIPTION OF THE PREFERRED EMBODIMENTS

Preferred embodiments of the present invention (hereinafter referred to as “embodiments”) will now be described with reference to the drawings.

### Structure of Preferred Embodiment

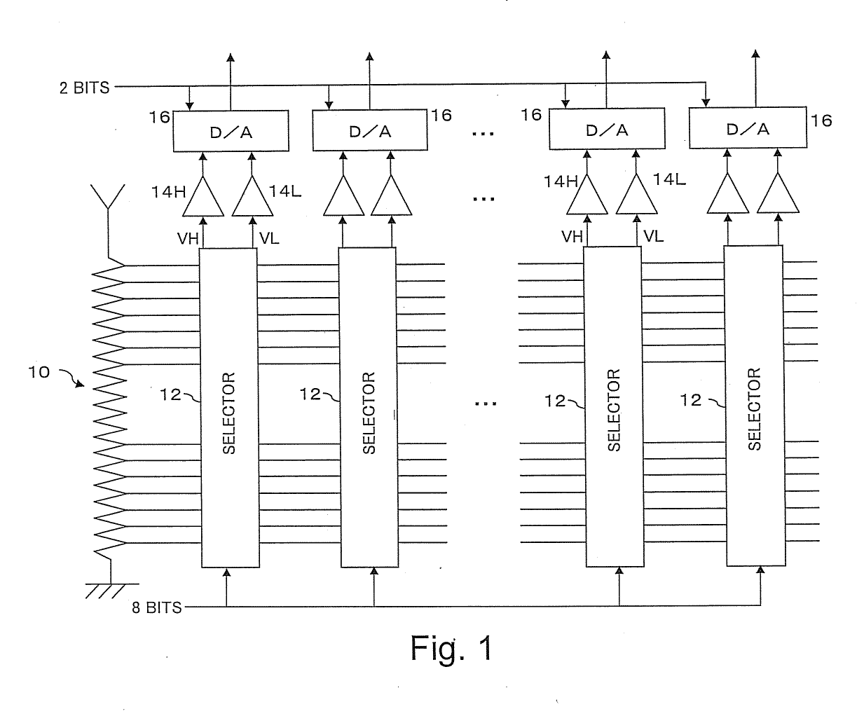

FIG. 1 is a diagram schematically showing a structure of a D/A converter according to a preferred embodiment of the present invention. The D/A converter converts a digital signal of 10 bits into an analog signal, and comprises inputs and outputs for a plurality (n) of channels.

An input digital signal of 10 bits is input in a divided state of 8 upper bits and 2 lower bits.

A resistor string 10 comprises 256 resistors which are connected in series, and has one terminal connected to a power supply and another terminal connected to ground. Therefore, 256 voltages can be obtained at 257 voltage output points of 0-256 which are the terminals of the resistors of the resistor string 10. n selectors 12 (12-1˜12-n) are connected to the 256 voltage output points of the resistor string 10.

The resistor string 10 and the selector 12 form a part of an upper (bit) converter. 8 upper bits of the input digital signal are input to each selector 12, and the input signal determines from which two voltage output points voltages are to be output. Each selector 12 selects and outputs voltages of both ends of one resistor determined by the input digital signal. In other words, voltages obtained from a voltage output point determined by the 8 upper bits of the input digital signal and from the voltage output point which is immediately above the determined point are the selected voltages of both ends. Alternatively, as will be described later, it is also possible to output voltages of two ends of a serial connection of a predetermined plurality of resistors.

A pair of outputs VH and VL of each selector 12 are stabilized by buffer amplifiers 14H and 14L, respectively, and are supplied to two-bit D/A converters 16 (16-1˜16-n) which are lower (bit) converters. Two lower bits of the input digital signal are input to the two-bit D/A converter 16, and the two-bit D/A converter 16 generates four voltages based on the input voltages VH and VL, and selects and outputs one of the generated voltages based on the input signal of the two lower bits. For this purpose, the D/A converter 16 comprises four resistors and selects one of the four voltages including one of VH or VL. Although in the present embodiment, VL is selected, it is also possible to select VH.

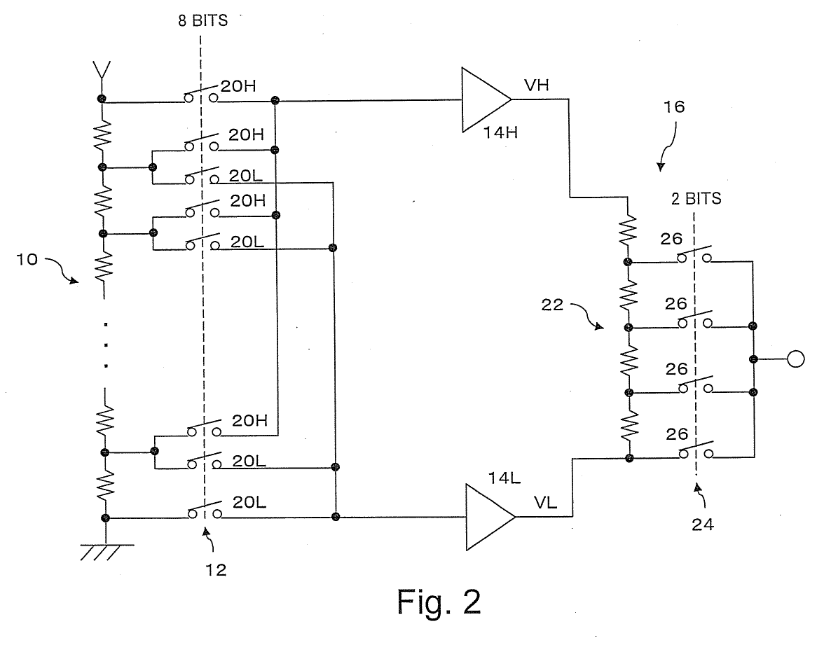

FIG. 2 shows structures of the selector 12 and the two-bit D/A converter 16. At the voltage output points of both ends of each resistor of the resistor string 10, two switches 20H for H and 20L for L are connected. At the upper side of the uppermost resistor of the resistor string 10, only the switch 20H for H is connected, and, at the lower side of the lowermost resistor, only the switch 20L for L is connected. Depending on the input upper-8-bit data, one of the L switches 20L and the H switch 20H immediately above the L switch 20L are selected, and VL and VH which are outputs indicating a range identified by the 8 upper bits are output for the data of the 8 upper 8 bits.

The two-bit D/A converter 16 comprises a resistor string 22 having four resisters which are connected in series and a selector 24. VL and each connection point between the four resistors are connected to a switch 26 of the selector 24 and are connected to an output terminal through four switches 26. The switches 26 are switched ON and OFF by the two lower bits. Specifically, one of the switches 26 is selected and switched ON by 0-3 of the data of the 2 lower bits, and a voltage corresponding to the lower two bits is output.

As described, voltages VH and VL corresponding to the 8 upper bits are supplied to the two-bit D/A converter 16, and a voltage between the voltages VH and VL identified by the two lower bits is output. Therefore, an analog voltage corresponding to data of 10 bits is output as a whole, and, thus, D/A conversion of 10 bits is executed.

As described, in the present embodiment, D/A conversion of 10 bits can be executed using the resistor string 10 of 8 bits and the resistor string 22 of 2 bits, and, thus, D/A conversion for digital data of 10 bits can be enabled with a total of 260 (256+4) resistors. By reducing the number of resistors used in the resistor string, it is possible to reduce a width of the D/A converter.

### Structure of Another Embodiment

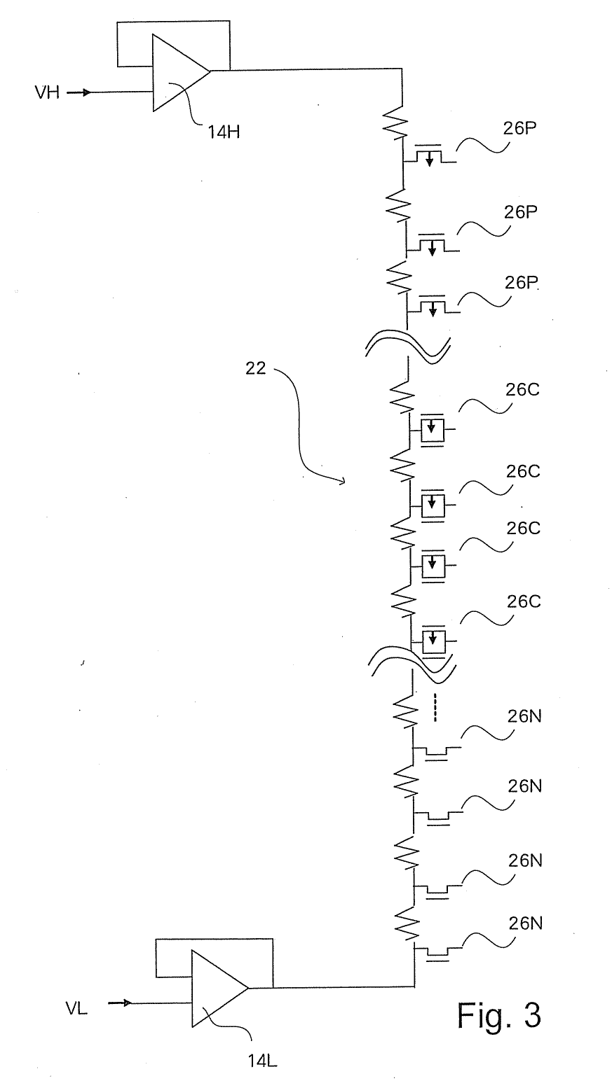

FIG. 3 shows a structure of a D/A converter according to another preferred embodiment of the present invention. In this example configuration, voltages that are distanced by 8 output points from a reference point are selected in the selector 12 of the resistor string 10 shown in FIG. 2. Specifically, a switch at an output point which is 8 output points above the voltage output point determined by the 8 upper bits and a switch at an output point which is 8 output points below the voltage output point determined by the 8 upper bits are selected, and the selected voltages are set as voltages VH and VL.

A two-bit D/A converter 16 comprises a resistor string 22 having 64 resistors. At the resistor string 22, NMOS switches 26N are connected to lower connection points of 32 lower resistors and PMOS switches 26P are connected to lower connection points of 28 upper resistors. In addition, CMOS (Complementary MOS) switches 26C are connected to lower connection points of 4 intermediate resistors.

When the input digital data of 10 bits is in a range of 0˜31, it is not possible to select, as the L switch 20L in the resistor string 10, a switch 20L which is 8 output points lower than the corresponding output point shown in FIG. 2. Thus, for such data, the L switch 20L and the H switch 20H identical to the case where the input digital data of 10 bits is 32 are selected, and one of the 32 lower NMOS switches 26N is selected corresponding to the data. When the input digital data of 10 bits is in a range of 992˜1023, switches 20L and 20H identical to the case where the input digital data of 10 bits is 991 are selected, and one of the 4 CMOS switches 26C and the 28 upper PMOS switches 26P is selected corresponding to the data.

When, on the other hand, the input digital data of 10 bits is in a range of 32˜991, one of the 4 CMOS switches 26C is selected as in a normal case. In other words, in a normal case, one of the CMOS switches 26C is selected by the two lower bits of the input data, D/A conversion for the two lower bits is executed, and an D/A conversion output for the digital data of 10 bits is obtained at the output.

In this manner, by selecting switches that are a predetermined number apart in place of controlling adjacent switches 20H and 20L and expanding a range of the VH-VL of the output of the resistor string 10, it is possible to reduce the error in the outputs VH and VL to a relatively lower value, and a highly precise D/A conversion can be executed. By using the 4 center resistors in the normal case in the resistor string 22 and employing CMOS switches 26C in these switches, it is possible to highly precisely output the voltage.

A D/A conversion precision of the 28 upper outputs and the 32 lower outputs is inferior compared to a D/A conversion precision of the 4 center outputs. In consideration of this, in the present embodiment, the upper and lower outputs are assigned to a range which is outside a normal operation guarantee range of the 10-bit D/A conversion. Alternatively, it is also possible to employ the CMOS switches for the 28 upper outputs and the 32 lower outputs.

In the above-described configuration, a configuration is employed in which 28 resistors are added on the upper side and 32 resistors are added on the lower side. The present invention, however, is not limited to such a configuration, and, alternatively, a configuration with, for example, 16 resistors, 8 resistors, and 4 resistors may be employed.

[Structure which uses Correction Data]

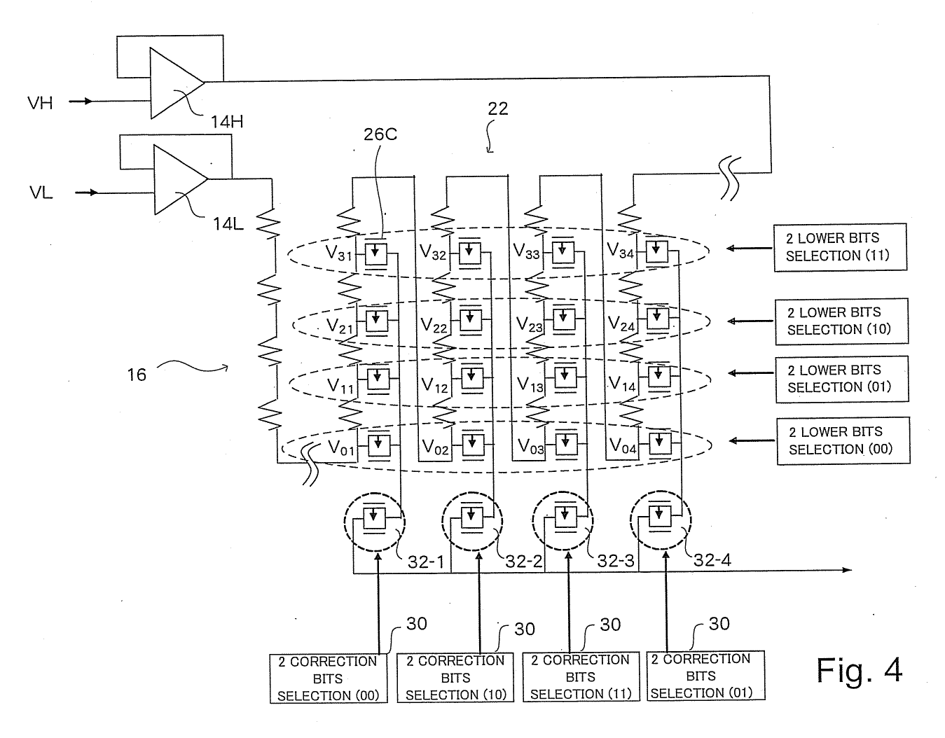

FIG. 4 shows a structure according another preferred embodiment of the present invention. In the exemplified configuration, four correction registers 30 are provided. A resistor string 22 comprises 16 switches 26 which are selected by two lower bits of the input data. More specifically, while in the configuration described above, one of the four CMOS switches 26 connected to the four center resistors is selected by the two lower bits of the input data in the normal case, in the present embodiment, one of groups of four CMOS switches 26C among the 16 CMOS switches connected to the 16 center resistors is selected by the two lower bits of the input data. The outputs of the four upper switches 26C are output through a correction switch 32-1, the outputs of the next four switches 26 are output through a correction switch 32-2, the outputs of the next four switches 26 are output through a correction switch 32-3, and the outputs of the four lower switches 26 are output through a correction switch 32-4. In addition, one of the correction switches 32-1˜32-4 is selected by the correction register 30.

As described, in this example configuration, four switches 26C which are connected to every four resistors of the 16 resistors which are connected in series are selected by the two lower bits of the input data, and one of the outputs of the four switches 26 is selected by the correction switch 32 which is controlled by the correction data. Therefore, with correction data of two bits, an output for an LSB (Least Significant Bit) of the input data can be shifted by an amount corresponding to four bits.

### [Structure for Setting Correction Data]

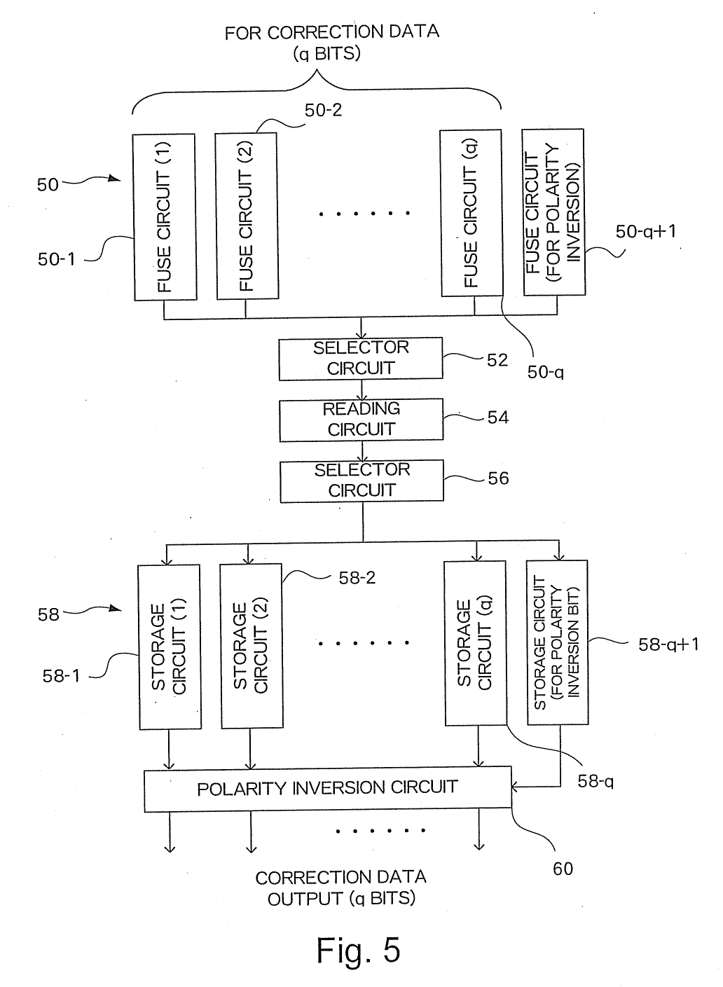

The correction data is stored in the correction register 30 at a startup of the system, and is preferably set individually using a fuse. FIG. 5 shows a structure of a correction data setting circuit using a fuse. A liquid crystal display panel is typically divided into a plurality of channels, and separate correction data are prepared for different channels. For example, when the size of the correction data is two bits and the liquid crystal display panel is divided into 13 channels, correction data of 26 bits is set by the fuse.

In the configuration shown in FIG. 5, while the size of the correction data is q bits, q+1 fuse circuits 50 (50-1˜50-q+1) are provided. In the fuse circuit 50, data of 0 or 1 is set depending on whether or not the fuse is cut by laser or the like. Among the fuse circuits 50, the fuse circuit 50-q+1 is a bit for polarity inversion. The polarity inversion bit determines whether or not contents of the fuse circuits of q bits 50-1˜50-q are to be inverted.

A reading circuit 54 is connected to the fuse circuits 50-1˜50-q+1 through a selector circuit 52. Because the reading circuit 54 reads the data of the fuse circuit 50 selected by the selector circuit 52, the reading of the fuse circuit 50 is a time divisional reading.

To the reading circuit 54, q+1 storage circuits 58-1˜58-q+1 are connected through a selector circuit 56. Therefore, the read data from the fuse circuits 50-1˜50-q+1 which are read by the reading circuit 54 are stored in the corresponding storage circuits 58-1˜58-q+1.

An output of the storage circuit 58 is input to a polarity inversion circuit 60. The polarity inversion circuit 60 outputs the read data from the fuse circuits of q bits 50-1˜50-q without inversion or with inversion depending on the content of the polarity inversion bit. The polarity inversion circuit 60 may have a structure, for example, in which q exclusive OR circuits (EX-OR) are provided, and one of the outputs from the storage circuits of q bits 58-1˜58-q and the polarity inversion bit are input to each exclusive OR circuit. With this structure, the polarity inversion circuit 60 determines, based on the state of the polarity inversion bit, whether the read data of the fuse circuits of q bits 50-1˜50-q are output with inversion or without inversion.

The outputs of the polarity inversion circuits 60 are output as the correction data of q bits.

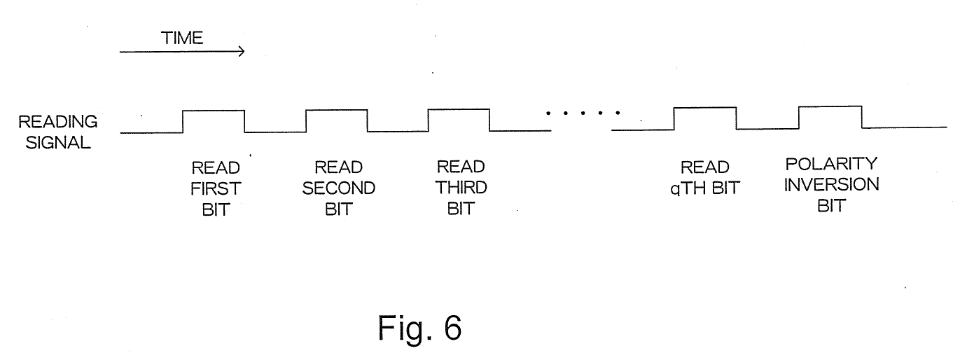

FIG. 6 shows a reading timing at the reading circuit 54. The selectors 52 and 56 are sequentially switched, and data of q+1 bits read from the fuse circuit 50 in a time divisional manner are stored in the storage circuits 58.

Next, correction data will be described. As an example, the non-cut state of the fuse may represent “1” and the cut state of the fuse may represent “0”, and the number of bits of the correction data may be 20 bits. The following three example cases will be described.

### (Case 1)

When correction data is “11111111110011110011”, the number of 1's is 16, the number of 0's is 4, and the polarity inversion bit is not cut. In this data, the number of bits to be cut is 4.

### (Case 2)

When correction data is “00010110000011101000”, the number of 1's is 7, the number of 0's is 13, and the polarity inversion bit is cut. In this case, the number of bits to be cut is 8. If there is no polarity inversion bit, the number of bits to be cut would be 13.

### (Case 3)

When correction data is “00000000000000000000”, the number of 1's is 0, the number of 0's is 20, and the polarity inversion bit is cut. In this case, the number of bits to be cut is 1. If there is no polarity inversion bit, the number of bits to be cut would be 20.

### [Overall Structure]

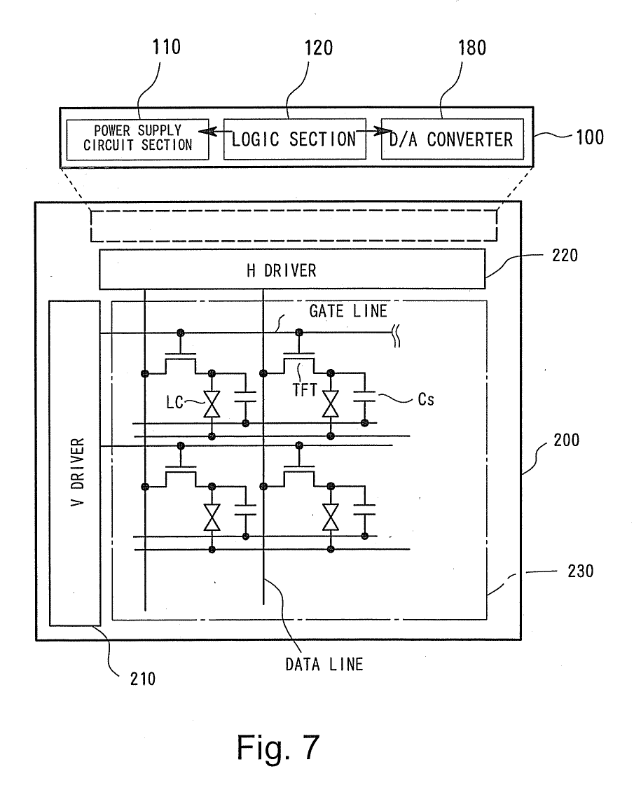

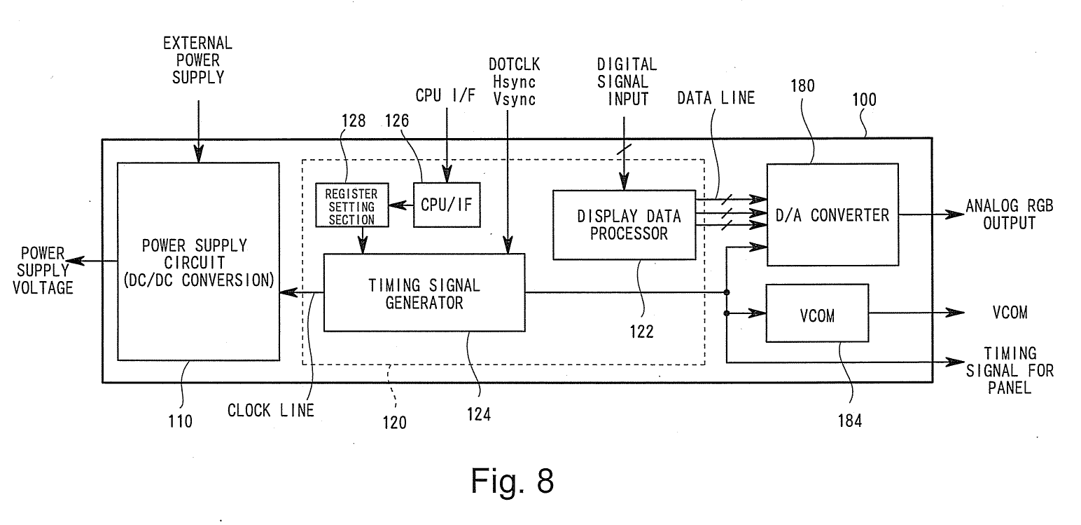

FIG. 7 schematically shows an overall structure of a display apparatus which uses a D/A converter according to a preferred embodiment of the present invention and FIG. 8 schematically shows a layout of an integrated driving circuit. The display apparatus is a flat display apparatus such as an LCD, and an active matrix LCD having a TFT as a switching element in each pixel and which executes display control for each pixel will be described as an example.

The display apparatus comprises an LCD panel 200 and an integrated driving circuit 100 having a circuit structure for driving the LCD panel 200. The LCD panel 200 is formed by affixing a pair of substrates such as glass on each of which an electrode is formed on a side opposing the other substrate, and sealing liquid crystal between the substrates. A pixel is formed at a position in which the electrodes oppose each other with the liquid crystal layer therebetween, and a plurality of such pixels are arranged in a matrix form in a display section 230 of the panel. When a driver circuit having a shift register circuit or the like for driving a pixel circuit such as a pixel TFT is to be built onto the panel, a vertical direction driver (V driver) 210 which sequentially controls a gate line and a horizontal direction driver (H driver) 220 which supplies display data to a data line at a predetermined timing are formed on one of the substrates of the panel (on a substrate on which the pixel TFT or the like is formed), at a peripheral portion of the display section 230 as shown in FIG. 7. The V driver 210 sequentially outputs a scan signal (gate signal) which controls ON and OFF states of the pixel TFT of the display section to a gate line extending along a row direction. The H driver 220 controls supply of analog display data, which is supplied from the integrated driving circuit 100 to be described later, to a data line extending along a column direction. With such a control, a voltage corresponding to analog display data is applied to liquid crystal and a storage capacitor Cs of each pixel through a pixel TFT which is controlled to be switched ON, an orientation of the liquid crystal is controlled for each pixel, and display is realized.

The integrated driving circuit 100 is mounted at a peripheral portion of the display section 230 of the LCD panel 200 by a COG method and has an elongated (long and narrow) shape, for example, along a row direction (horizontal scan direction) of the display section 230. In the integrated driving circuit 100, a power supply circuit section 110, a logic section 120 which can be formed with a logic circuit element, a D/A converting section which comprises a D/A converter 180, or the like are integrated as a single chip. In addition, the logic section 120 is placed at a center portion along a long side direction of the integrated driving circuit 100 having the elongated shape, and the power supply circuit section 110 and the D/A converter 180 are provided adjacent to the logic section 120 and at regions on the left and right along the long side direction with the logic section 120 therebetween.

FIG. 8 is a diagram showing a structure of a driving control circuit of the display apparatus. The logic section 120 is primarily constructed as a logic circuit element which can process digital data, and comprises a display data processor 122, a timing signal generator 124, a CPU interface (CPU/IF) 126, and a register setting section 128. The display data processor 122 is a signal processing circuit which processes a color video signal from outside into a display signal suitable for display on the LCD panel. The display data processor 122 converts, for example, a serial digital video signal supplied from the outside into a parallel signal, applies a process such as a matrix conversion and thinning-out according to the type of the signal, execute an image quality adjusting process such as γ correction, and outputs the obtained processed R, G, and B digital display data to the D/A converter 180 to be described later.

The timing signal generator 124 generates various timing signals necessary in the V driver 210 and the H driver 220 such as an H direction clock CKH, a V direction clock CKV, a horizontal start signal STH, and a vertical start signal STV based on a dot clock (DOTCLK) and synchronization signals (Hsync, Vsync) supplied from the outside. In addition, the timing signal generator 124 generates a power supply clock signal necessary for generating, in the power supply circuit section 110, a power supply used in the panel. Moreover, because the liquid crystal must be AC driven in the LCD panel 200, the timing signal generator 124 generates a polarity inversion timing signal for periodically inverting a polarity of the display data and supplies the polarity inversion timing signal to the D/A converter 180 and a VCOM output section 184.

The CPU/IF 126 receives an instruction from a CPU or the like (not shown) of the device on which the LCD panel 200 is mounted and analyzes the instruction, and supplies the instruction to the register setting section 128. The register setting section 128 maintains the instruction from the CPU, and supplies a control signal according to the instruction to the timing signal generator 124. The instructions transmitted from the CPU include, for example, an adjustment instruction of a display position on the display panel, a contrast adjustment instruction, or a power save control instruction.

A resister string type converter may be employed for the D/A converter 180, and the D/A converter 180 converts the R, G, and B digital display data signals which are output from the display data processor 122 into R, G, and B analog display data having corresponding voltage values. The obtained analog display data is supplied to the data line of the LCD panel 200 through an amplifier (not shown) provided at an output stage of the integrated driving circuit 100.

The VCOM output section 184 generates a common electrode signal VCOM or the like to be supplied to a common electrode which is placed opposing a pixel electrode, which is individual for each pixel of the LCD panel 200, with the liquid crystal layer therebetween, and outputs the common electrode signal VCOM or the like. A driving method is employed in which a polarity of the potential of the common electrode is also periodically inverted. Thus, the VCOM output section 184 receives the polarity inversion signal from the timing signal generator 124 and periodically inverts the polarity of the common electrode signal VCOM. The VCOM output section 184 is provided in a region of the integrated driving circuit 100 at a side opposite of the power supply circuit section 110 and on a same side as the D/A converter 180, and forms a part of an analog voltage output section (which primarily includes a driver output section to the H driver and V driver) to the LCD panel 200 along with the D/A converter 180.

The power supply circuit section (DC/DC converter) 110 may be constructed from, for example, a charge-pump circuit, a switching regulator, or the like, and generates an ON level and an OFF level of a gate signal and a high voltage (8.5 V, for example) used for a control potential level of the storage capacitor Cs which are necessary in the LCD panel 200, from an external power supply of approximately 3 V using the power supply clock signal from the timing signal generator 124, and supplies the power supply to the panel 200.

By employing, as the resistor string of the D/A converter of the D/A conversion section, a two-part structure as described above, it is possible to easily realize the elongated and narrow and long chip.

What is claimed is:

1. A digital-to-analog converter which converts an input digital signal of (n+m) bits (where each of n and m is an integer greater than or equal to 2) into an analog signal, the digital-to-analog converter comprising:
an upper conversion section which comprises a resister string and which converts a signal of m upper bits of the input digital signal into a pair of analog signals corresponding to the signal of the m upper bits and having a width corresponding to n lower bits, and
a lower conversion section which comprises a resister string, which divides a pair of outputs from the upper conversion section, and which converts into an analog signal selected according to a signal of n lower bits.

2. The digital-to-analog converter according to claim 1, further comprising
a pair of buffer amplifiers which stabilize the pair of outputs of the upper conversion section, respectively.

3. The digital-to-analog converter according to claim 2, wherein
the upper conversion section outputs a pair of analog signals having a width of p bits (where p is an integer greater than n), and
the lower conversion section selects an output based on a signal of n bits using a portion within a conversion width of p bits (where p is an integer greater than or equal to 3) corresponding to n bits.

4. The digital-to-analog converter according to claim 1, wherein
the upper conversion section outputs a pair of analog signals having a width of p bits (where p is an integer greater than n), and
the lower conversion section selects an output based on a signal of n bits using a portion within a conversion width of p bits (where p is an integer greater than or equal to 3) corresponding to n bits.

5. The digital-to-analog converter according to claim 4, wherein
when the input digital signal has a large value or a small value which is outside of an operation guarantee range, the lower conversion section outputs an output using a portion other than the portion corresponding to n bits.

6. The digital-to-analog converter according to claim 1, wherein
a plurality of the lower conversion sections having an identical structure are provided, and one of the outputs is selected according to a correction bit which is supplied separately from the input digital signal.
